(19) United States
(12) Patent Application Publication
(10) Pub. No.: US 2008/0157198 A1
(43) Pub. Date: Jul. 3, 2008

(54) HIGH-VOLTAGE SEMICONDUCTOR DEVICE AND METHOD OF MANUFACTURING THEREOF

(75) Inventors: Ji Hong KIM, Seoul (KR); Sang Hun JUNG, Incheon (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/926,023

(22) Filed: Oct. 28, 2007

(30) Foreign Application Priority Data
Dec. 29, 2006 (KR) 10-2006-0137277

(51) Int. Cl. H01L 29/78; H01L 21/336

(52) U.S. Cl. 257/339; 438/294; 257/E21.417; 257/E29.256

(57) ABSTRACT

A high-voltage semiconductor device capable of preventing a substrate current from forming is disclosed. The method of manufacturing the high-voltage semiconductor device comprises forming a well in a semiconductor substrate, forming a device isolation film in a portion of the semiconductor substrate, forming a series of drift regions below the surface of the semiconductor substrate, forming a gate electrode on the surface of the semiconductor substrate so as to overlap a portion of at least one drift region, and forming a source and a drain region below the surface of the semiconductor substrate drift regions formed on opposing sides of the gate electrode. Advantageously, the substrate current of the semiconductor device is reduced and the operational withstand voltage is increased, improving the characteristics of the high-voltage transistor.

### CROSS-REFERENCES AND RELATED APPLICATIONS

This application claims the benefit of Korean Patent Application No. 10-2006-0137277, filed on Dec. 29, 2006, which is hereby incorporated by reference in its entirety.

### BACKGROUND OF THE INVENTION

1. Field of the Invention

The present invention relates to technology for manufacturing a high-voltage semiconductor device. More specifically, the present invention relates to a high-voltage semiconductor device capable of preventing substrate currents due to high voltages and a method of manufacturing the same.

2. Discussion of the Related Art

Typically, in high-voltage semiconductor devices, the breakdown voltage decreases as the gate voltage increases. Thus, in order to apply a high voltage to a gate, a semiconductor device with a high breakdown voltage is needed.

Typically, a double diffused metal-oxide-semiconductor (DMOS) structure wherein drift regions are formed with an elongated lateral path which extends between the drain and source diffusion regions is used. The drift regions decrease the high voltage from a channel region controlled by the gate to about 20 V which is applied between the drain and the source. Ideally, the drift regions should be long with a low concentration, so as to maximize the voltage capacity of the transistor. One difficultly in using the drift regions, however, is that the drift regions enable elements to have a relatively high resistance when the transistor is turned on. Additionally, using drift regions increases the size of the device while decreasing the current per unit width.

FIG. 1 is a cross-sectional view showing the structure of a high-voltage transistor of the related art, and FIG. 2 is a graph illustrating the problems of the high-voltage transistor of the related art. As shown in FIG. 1, the NMOS semiconductor device of the related art includes a semiconductor substrate 10, a high-voltage P-type well region (HPWELL) 12, a gate electrode 16, an N-type drift region 14, and a source/drain region 18. In this example, the semiconductor substrate 10 is a P-type or N-type substrate and the high-voltage P-type well region (HPWELL) 12 is formed in the semiconductor substrate 10.

The gate electrode 16 is formed on the semiconductor substrate 10 and includes a gate oxide film 16a, a gate 16b, and a spacer 16c. The N-type drift regions 14 are formed in active regions of the semiconductor substrate 10 under the spacers 16c. The source/drain region 18 includes an N⁺ source region 18a and an N⁺ drain region 18b formed in the N-type drift region 14. The NMOS semiconductor device of the related art is designed such that a gate poly and a drift junction do not overlap.

The semiconductor device of the related art is designed so that the drive voltage has a margin of up to 7 V, since the semiconductor device withstands up to 10 V when the device's drain voltage-current curve (Vd-Id curve) is measured.

In contrast, the high-voltage transistor of the related art has an operational withstand voltage, which is the amount of voltage the drain has to withstand when the transistor is turned on, is low. In situations where the gate-source voltage Vgs is low and a drain-source voltage Vds is high, an electric field converges on the surface of the substrate on the edge of the drain. Then when a channel current path of the transistor contacts the portion where the electric field has converged, a phenomenon referred to as impact ionization occurs. Due to the impact ionization phenomenon, a large substrate current, referred to as Isub, occurs and thus the operational withstand voltage of the device is reduced.

### BRIEF SUMMARY OF THE INVENTION

Accordingly, the present invention is directed to a high-voltage semiconductor device and a method of manufacturing the same, which substantially obviates one or more problems, limitations, or disadvantages of the related art.

One object of the present invention is the ability to provide a high-voltage semiconductor device with a modified structure which is capable of improving the properties of the substrate current. Another object of the present invention is the ability to provide a high-voltage semiconductor device which is capable of reducing the substrate current so as to improve the operational withstand voltage.

Additional advantages, objects, and features of the invention will be set forth in part in the following description and will become apparent to those having ordinary skill in the art upon examination of the description or may be learned from practice of the invention. The objectives and other advantages of the invention may be realized and attained by the structure particularly pointed out in the written description, claims, and appended drawings.

To achieve these objects and other advantages and in accordance with the purpose of the invention, one aspect of the invention is a high-voltage semiconductor device which includes a well which is formed in a surface of a semiconductor substrate, a series of drift regions formed below the surface of the semiconductor substrate by implanting and diffusing ions into the well, a source region and a drain region which are formed below the surface of the semiconductor substrate by implanting ions into the drift region, and a gate electrode formed on the surface of the semiconductor substrate so as to overlap a portion of at least one drift region.

In another aspect of the present invention is a method of manufacturing a high-voltage semiconductor device. The method comprises forming a well in a semiconductor substrate, forming a device isolation film in a portion of the semiconductor substrate, forming a series of drift regions below the surface of the semiconductor substrate, forming a gate electrode on the surface of the semiconductor substrate so that the gate electrode overlaps a portion of at least one drift region, and forming a source region and a drain region below the surface of the semiconductor substrate in drift regions on opposing sides of the gate electrode.

It is to be understood that both the foregoing general description and the following detailed description of the present invention are exemplary and so as to provide further explanation of the invention as claimed.

### BRIEF DESCRIPTION OF THE DRAWINGS

The accompanying drawings are included to provide a further understanding of the invention and are incorporated in and constitute a part of this application. The drawings illustrate embodiment(s) of the invention and together with the description serve to explain the principle of the invention. In the drawings:

FIG. 1 is a cross-sectional view showing the structure of a high-voltage transistor known in the related art;

FIG. 2 is a graph explaining the problems of the high-voltage transistors known in the related art;

FIGS. 3A to 3F are cross-sectional views showing a method of forming a high-voltage transistor according to an embodiment of the present invention;

FIG. 4 is a cross-sectional view showing the structure of a high-voltage transistor according to another embodiment of the present invention; and

FIG. 5 is a graph illustrating the advantages of the high-voltage transistor of the present invention.

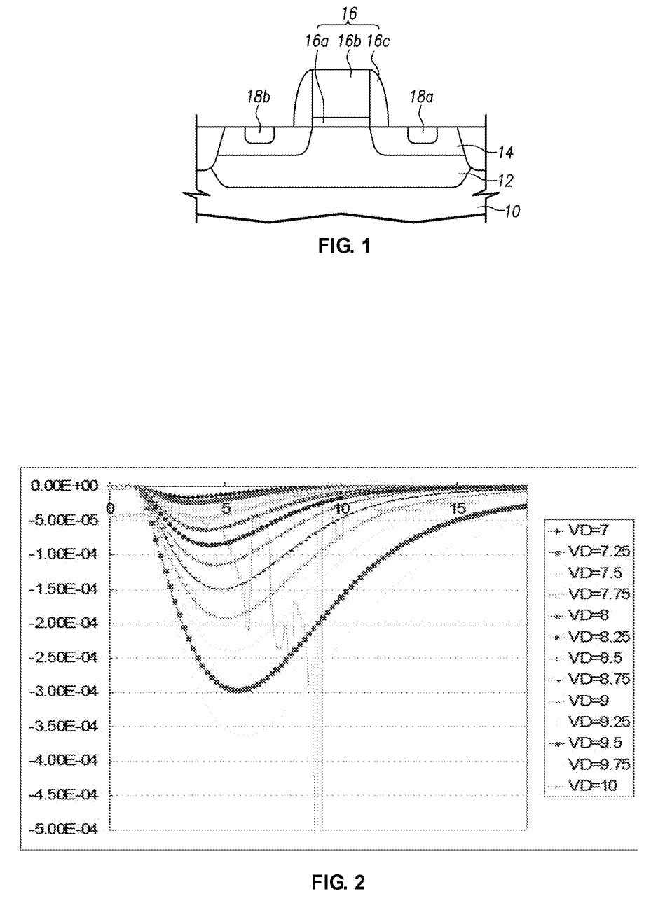

### DETAILED DESCRIPTION OF THE INVENTION

Hereinafter, a high-voltage semiconductor device and a method of manufacturing the same will be described with reference to the accompanying drawings.

Additional advantages, objects, and features of the invention will be more readily apparent from the following detailed description and accompanying drawings. The configuration and operation of embodiments of the present invention will be described with reference to the accompanying drawings. The configuration and operation of the invention described and shown in the drawings constitutes at least one embodiment of the invention, without limiting the spirit or scope of the amended claims.

The structure of the high-voltage semiconductor of the present invention and the method of manufacturing the same will be described concentrating on the high-voltage transistor, however, the present invention is not limited to the transistor.

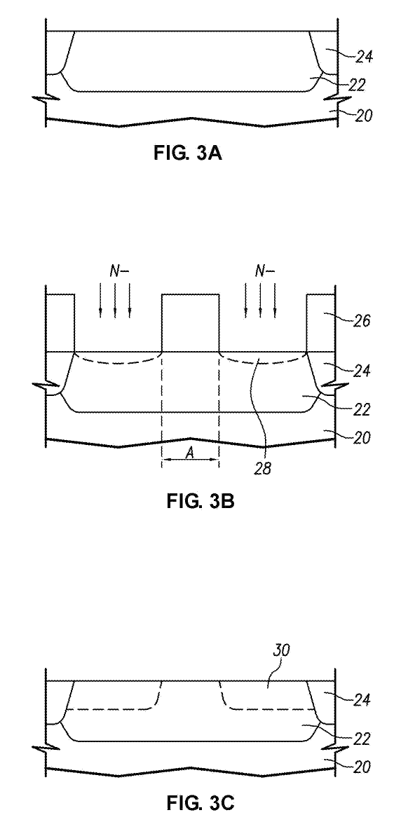

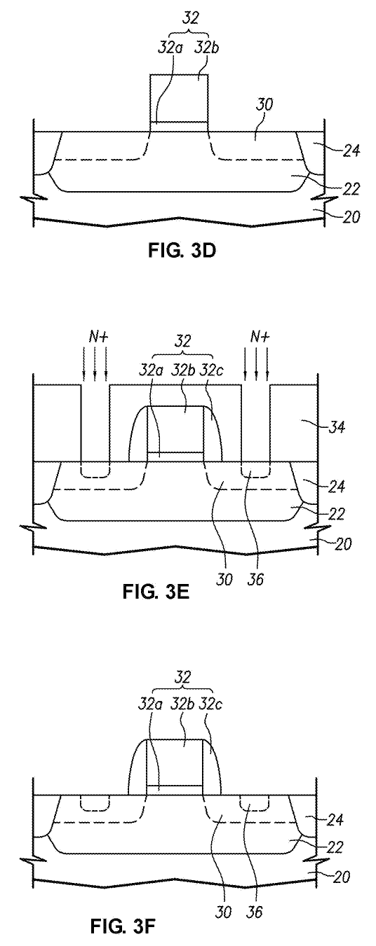

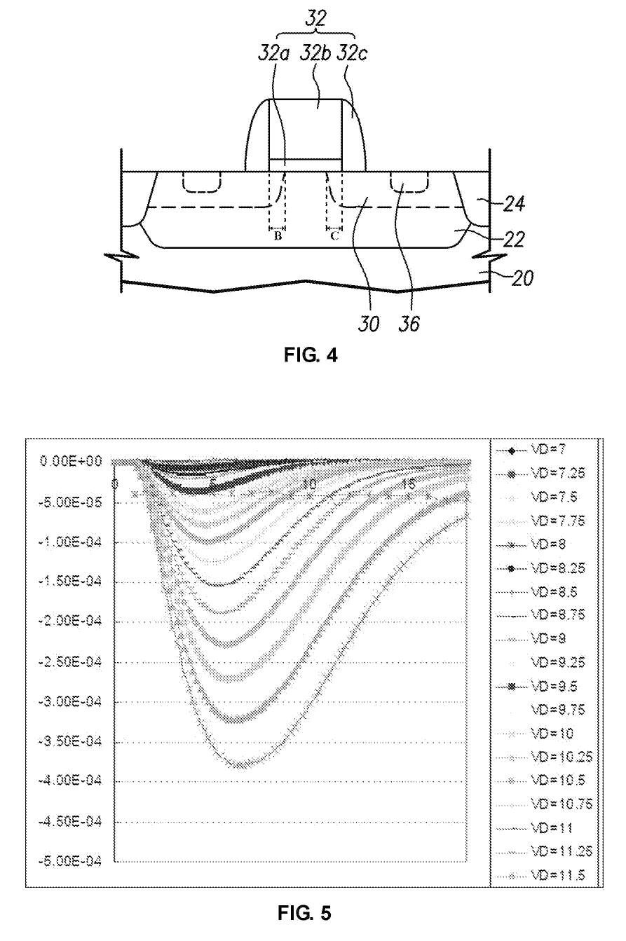

FIGS. 3A to 3F are cross-sectional views showing a method forming a high-voltage transistor according to an embodiment of the present invention. Furthermore, FIG. 3F is a cross-sectional view showing the structure of the high-voltage transistor according to another aspect of the present invention and FIG. 4 is a cross-sectional view showing the structure of a high-voltage transistor according to another embodiment of the present invention.

As shown in FIGS. 3F and 4, the high-voltage transistor of the present invention includes a P-type well 22 formed by implanting a low concentration of a P-type dopant into the surface of a semiconductor substrate 20 which includes a high-voltage transistor forming region and a low-voltage transistor forming region. The high-voltage transistor further includes a device isolation film 24 formed by a device isolation process so as to isolate the elements, such as the transistor components, formed on the semiconductor substrate. In this example, the low-voltage transistor forming region is not shown and the description thereof will be omitted.

An N-type drift region 30 is formed in the P-type well 22 by diffusing an N-type dopant into the well 22. In this example, the N-type drift regions 30 may overlap a portion of a channel region A adjacent to a source region or a drain region of the semiconductor substrate 20, depending on how the gate electrode is later formed. Therefore, a structure wherein the drift regions 30 do not overlap the portion of the gate electrode as shown in FIG. 3f, and a structure in which the drift regions 30 overlap with portions of the gate electrode as shown in FIG. 4.

A gate electrode 32 is formed by sequentially laminating a gate oxide film 32a and a gate 32b on the semiconductor substrate 20. The gate electrode 32 has spacers 32c. Then, a source region and a drain region 36 are formed in the N-type drift regions 30 by implanting a high concentration of an N-type dopant into the surface of the exposed semiconductor substrate 20.

The process for forming a semiconductor transistor of the invention with the previously described structure will now be described. First, as shown in FIG. 3A, a low concentration of a P-type dopant is ion-implanted into the surface of the substrate 20 and in the high-voltage transistor forming region and the low-voltage transistor forming region so to form the P-type well 22.

Then, a general device isolation process is performed in order to form the device isolation film 24 for isolating the elements of the transistor which subsequently formed on the substrate 20. Here, the device isolation film 24 is preferably formed using a shallow trench isolation (STI) process. In this example, the low-voltage transistor forming region is not shown.

Next, as shown in FIG. 3B, an ion implantation mask pattern 26 is formed on the device isolation film 24 so as to generate a high breakdown voltage. An ion implantation mask pattern 26 is also formed in the channel region A where the gate electrode of the high-voltage transistor region will be formed.

Subsequently, an N-type dopant is selectively ion-implanted into the surface of the exposed substrate 20 using an ion implantation mask pattern 26 formed on the surface of the exposed substrate 20. Using the ion implantation mask pattern 26 as a mask, an N-type doped layer 28 is formed below the surface of the exposed substrate 20 in an ion implantation process. Then, as shown in FIG. 3C, the ion implantation mask pattern 26 is removed and the substrate 20 with the N-type doped layer 28 is annealed at a temperature of between 1000° C. and 1200° C. Thus, the N-type dopant is diffused into the substrate 20 in order to form the N-type drift regions 30.

The ion implantation mask pattern 26 according to the present invention may be formed so as to shield the entire channel region A or may be formed so as to expose a portion of the channel region A. In one embodiment, the ion implantation mask pattern 26 may be formed so as to expose a portion of the channel region A that is adjacent to the source region, and in another embodiment the ion implantation mask pattern may be formed so as to expose the channel region A adjacent to the drain region. Thus, when the gate electrode is subsequently formed, the N-type drift regions 30 may overlap a portion of the channel region A.

As shown in FIG. 3D, the gate oxide film and a polysilicon layer are then formed on the entire surface of the semiconductor substrate 20, including the N-type drift regions 30. The gate oxide film and polysilicon layer each have a thickness which is suitable for the voltage applied to the gate of a high-voltage device.

Next, a standard photolithography process and etching process are performed in order to selectively remove the polysilicon layer and the gate oxide film from the surface except in the region where the gate electrode will be formed. Accordingly, the gate electrode 32 is formed by sequentially laminating the gate oxide film 32a to form a gate 32b.

Alternatively, the mask pattern used to form the gate electrode may be formed so as to match the size of the channel region A or may be formed so as to overlap a portion of the N-type drift regions 30 on at least one side of the channel region A. In either case, the N-type drift regions 30 may overlap a portion of the channel region A.

In the present invention, the width of the mask pattern for forming the gate electrode may be adjusted. Thus, the degree that N-type drift regions 30 overlap the gate electrode may be adjusted by adjusting the width of the ion implantation mask pattern 26.

After the gate electrode 32 is formed, as shown in FIG. 3E, spacers 32c are formed on both walls of the gate electrode 32 by depositing an oxide film on the entire surface of the substrate 20 so as to cover the gate electrode 32. Then, the spacers 32c are formed by performing an etch-back process so as to expose the gate 32b.

Then, a photoresist pattern 34 is formed so as to cover the gate electrode 32 and spacers 32c. In this example, a photoresist pattern 34 acting as an ion implementation mask is used to form the source and drain regions 36. Then a high concentration of an N-type dopant is ion-implanted into the surface of the substrate which is exposed by the photoresist pattern 34. Using this process, the source and drain regions 36 are formed in the N-type drift regions 30.

Next, as shown in FIG. 3F, an ashing/strip process is performed in order to remove the photoresist pattern 34 used as an ion implantation mask.

In the present invention, a low doped junction is required in order to form a transistor which is capable of operating at a high voltage. Thus, a process for diffusing the dopant ions at a high temperature is performed after the ion implantation process.

As previously mentioned, in one embodiment of the present invention, the N-type drift regions 30 are formed under the gate electrode 32 so as to overlap the portion of the channel region A. Therefore, the N-type drift regions 30 overlap at least one side of the gate oxide film 32a and the gate 32b under the gate electrode 32. Additionally, the N-type drift regions 30 may overlap at least one area below the spacers 32c of the gate electrode 32.

Thus, the N-type drift regions 30 may be formed below the surface of the semiconductor substrate 20 so as to overlap the channel region. Therefore, when a drain-source voltage Vds higher than a gate-source voltage Vgs is applied to the transistor, the surface of the portion of the drain region is depleted and the channel current flowing in the transistor is prevented from contacting the surface portion of the edge of the drain where the electric field converges. Since the channel current flows in the low-concentration drain layer formed by ion-implanting a low concentration dopant in the drain layer under a depletion layer, the substrate current Isub is reduced and an operational withstand voltage is improved.

FIG. 5 shows the results of an experiment for measuring the properties of the high-voltage transistor of the present invention. As shown in FIG. 5, when the N-type overlaps the portion of the channel region under the gate electrode, the drain-source voltage Vds endures 11.5 V. Thus, the channel current flows under the depletion layer away from the surface of the semiconductor substrate, meaning that the surface scattering of channel current carriers is reduced. Thus, drive characteristics of the transistor are improved.

A high-voltage semiconductor device and a method of manufacturing the same according to the invention have been described with reference to a preferred embodiment, which is disclosed in the present specification and shown in the drawings. Although specific terms are used, these terms are used to simplify the explanation of technical aspects of the invention and to facilitate the understanding of the invention in a generic sense, and are not intended to define or limit the scope of the invention. It will be understood by those skilled in the art that various modifications to the present invention may be made without departing from the essential characteristics of the present invention. Thus, it is intended that the present invention covers the modifications and variations of this invention provided they come within the scope of the appended claims and their equivalents.

As described above, since a portion of the N-type drift regions overlap a portion of the channel region under a gate electrode, the substrate current Isub is reduced and the operational withstand voltage is improved. Accordingly, the characteristics of the transistor are improved.

What is claimed is:

1. A high-voltage semiconductor device comprising:
a well formed in a surface of a semiconductor substrate;
a series of drift regions formed below the surface of the semiconductor substrate by implanting and diffusing ions into the well;
a source region and a drain region formed below the surface of the semiconductor substrate by implanting ions into the drift regions; and
a gate electrode formed on the surface of the semiconductor substrate so as to overlap a portion of one drift region.

2. The high-voltage semiconductor device according to claim 1, wherein the well is a P-type well formed by ion-implanting a low concentration of a P-type dopant into the surface of the semiconductor substrate.

3. The high-voltage semiconductor device according to claim 1, wherein the drift regions are N-type drift regions formed by ion-implanting an N-type dopant into an upper portion of the surface of the well which is exposed by a mask pattern so as to form a doped layer at the upper side of the well and diffusing the doped layer.

4. The high-voltage semiconductor device according to claim 1, wherein the gate electrode includes a gate oxide film and a gate, which are sequentially laminated on the surface of the semiconductor substrate, along with spacers are formed on both sides of the laminated gate oxide film and gate.

5. The high-voltage semiconductor device according to claim 4, wherein at least one of the spacers overlaps a portion of one drift region.

6. The high-voltage semiconductor device according to claim 4, wherein at least side of the laminated gate oxide film and gate overlaps a portion of at least one drift region.

7. The high-voltage semiconductor device according to claim 1, wherein at least one drift region is formed under the gate electrode so as to extend into a portion of a channel region of the substrate located below the gate electrode.

8. A method of manufacturing a high-voltage semiconductor device, the method comprising:
forming a well in a semiconductor substrate;
forming a device isolation film in a portion of the semiconductor substrate;
forming a series of drift regions below the surface of the semiconductor substrate;
forming a gate electrode on the surface of the semiconductor substrate so as to overlap a portion of at least one drift region; and
forming a source region and a drain region below the surface of the semiconductor substrate within drift regions on opposing sides of the gate electrode.

9. The method according to claim 8, wherein at least one drift region is formed so as to extend to a portion of the substrate which is below where the gate electrode will be formed on the side of the gate electrode where the source region will be formed.

10. The method according to claim 8, wherein at least one drift region is formed so as to extend to a portion of the substrate which is below where the gate electrode will be formed on the side of the gate electrode where the drain will be formed.

11. The method according to claim 8, wherein two drift regions are formed so as to extend to portions of the substrate which are below where the gate electrode will be formed on the opposing sides of the gate electrode where the source and drain regions will be formed.

12. The method according to claim 11, wherein the drift region formed on the substrate where the source region will be formed extends further into portions of the substrate below where the gate electrode will be formed than portions of the drift region formed on the substrate where the drain region will be formed.

13. The method according to claim 11, wherein the drift region formed on the substrate where the drain region will be formed extends further into portions of the substrate below where the gate electrode will be formed than portions of the drift region formed on the substrate where source region will be formed.

14. The method according to claim 8, wherein the well is formed by ion-implanting a low concentration of a P-type dopant into the surface of the semiconductor substrate.

15. The method according to claim 8, wherein forming the drift regions comprises:
forming a mask pattern for implanting ions into the well;
implanting an N-type dopant into the surface exposed by the formed mask pattern in order to form a doped layer; and
diffusing the doped layer to a portion of the surface below where the gate electrode will be formed.

16. The method according to claim 15, wherein the semiconductor substrate is annealed at a temperature of between 1000° C. and 1200° C. in order to diffuse the doped layer.

17. A method of manufacturing a transistor for a high-voltage semiconductor device, the method comprising:
forming a well in a semiconductor substrate;
forming a device isolation film in a portion of the semiconductor substrate;
forming a series of drift regions below the surface of the semiconductor substrate by forming a mask pattern for implanting ions into the well, implanting an N-type dopant into the surface exposed by the formed mask pattern in order to form a doped layer, and diffusing the doped layer to a portion of the surface below where the gate electrode will be formed;
forming a gate electrode on the surface of the semiconductor substrate so as to overlap a portion of two drift regions on opposing sides of the gate electrode; and
forming a source region below the surface of the semiconductor substrate in one drift region on one side of the gate electrode and a drain region below the surface of the semiconductor substrate in the drift region on the opposing side of the gate electrode.

18. The method according to claim 17, wherein the drift region formed on the substrate where the source region will be formed extends further into portions of the substrate below where the gate electrode will be formed than portions of the drift region formed on the substrate where the drain region will be formed.

19. The method according to claim 17, wherein the drift region formed on the substrate where the drain region will be formed extends further into portions of the substrate below where the gate electrode will be formed than portions of the drift region formed on the substrate where source region will be formed.

20. The method according to claim 17, wherein the well is formed by ion-implanting a low concentration of a P-type dopant into the surface of the semiconductor substrate.
